(19) United States
(12) Patent Application Publication
(10) Pub. No.: US 2010/0014224 A1
(43) Pub. Date: Jan. 21, 2010

(54) Housing for Receiving an Electronic Assembly

(75) Inventor: Karl Smirra, Wasserburg (DE)

Correspondence Address: LERNER GREENBERG STEMER LLP, P O BOX 2480, HOLLYWOOD, FL, 33022-2480, US

(73) Assignee: CONTINENTAL AUTOMOTIVE GMBH, Hannover (DE)

(21) Appl. No.: 12/374,128

(22) PCT Filed: May 14, 2007
(86) PCT No.: PCT/EP2007/054640

§ 371 Date: Jan. 26, 2009

(30) Foreign Application Priority Data
Jul. 19, 2006 (DE) 10 2006 033 475.2

(51) Int. Cl. H05K 5/00

(52) U.S. Cl. 361/679.01

(57) ABSTRACT

A housing for receiving an electronic assembly includes a housing body having two openings opposite to each other, and two housing covers for closing the openings. At least one U-shaped clamp spring has a base and two legs. The clamp spring can be placed onto the housing in such a way that the legs exert forces onto the housing cover that are opposite to one another and interact which each other, with which the housing covers are fixed to the housing body. The clamp spring, which is placed on from the exterior, encompassing the housing body and thereby fixing the housing covers to the housing body in a force-locking manner, can be easily mounted and dismounted any number of times and ensures an installation of the housing covers onto the housing body that is resistant to vibrations.

The invention relates to a housing for receiving an electronic assembly, comprising a housing body having two openings opposite to each other and two housing covers for closing the openings.

With housings of this type, it is known to fasten the housing cover to the housing body by means of screws. This represents a secure and detachable connection, which is however associated with relatively high labor costs in the case of an initial assembly and potential subsequent repair measures.

The document DE 90 00 470 U1 discloses providing the housing cover with a locking plate which engages in a snap-in slit on the housing body. Such a housing can however be easily mounted, dismounting nevertheless frequently proves to be difficult, particularly if the catch mechanism is designed for a high holding force or if the retainers engage into the housing body from the interior.

The object of the invention is to specify a housing of the type specified in the introduction in which the housing cover can be securely fastened to the housing body and can be mounted and dismounted quickly and easily.

The object is achieved by a housing of the said type, in which at least one u-shaped clamp spring is provided with a base and two legs, which can be placed onto the housing such that the legs exert forces onto the housing cover that are opposite to one another and interact with each other, by which the housing covers are fixed to the housing body. The clamp spring placed on from the exterior, encompassing the housing body and thereby fixing the housing covers to the housing body in a force-locking manner can be easily mounted and dismounted any number of times. With a suitable material selection and dimensioning, sufficiently large holding forces are exerted by the clamp spring onto the housing covers, by means of which the housing body is securely closed with the housing covers in a manner that is resistant to vibrations. The clamp spring is also cost-effective, and can be manufactured for instance bent in one piece from wire. In particular, this fastening method lends itself to the housing covers, if a section of a hollow profile is used as a housing body. Corresponding hollow profiles can be manufactured cost-effectively by extrusion or in an extrusion process involving different materials, for instance aluminum or plastic. Potentially required receiving elements for the electronic assembly may be already molded in the profile during the manufacturing method.

In an advantageous embodiment of the invention, the clamp spring has a locking element on one or both legs. The locking element is particularly advantageously formed by a hook-shaped or half-moon-shaped arched region of the leg or by a spring eye at the end of the leg. Locking elements of this type prevent the clamp spring from slipping out of the position provided. Slippage is on the other hand possible in some circumstances as a result of vibrations, to which the housing is exposed.

According to a further advantageous embodiment of the invention, two clamp springs are provided which are connected to one another. The two clamp springs are particularly advantageously connected by way of a rod running at right angles to its base and at right angles to its legs. The mounting of the housing is further simplified in this way since the two clamp springs which are connected to one another can be assembled with a handle.

According to a further advantageous embodiment of the invention, at least one of the housing covers has a first holding element, which can be coupled in a form-locking manner with the locking element of the at least one clamp spring. The first holding element is particularly advantageously a depression in the at least one housing cover or a raised region of the least one housing cover. Depressions or raised regions can be easily introduced into the housing cover during the manufacturing process and combined with the locking elements of the clamp spring to protect this against slippage.

In a further advantageous embodiment of the invention, at least one of the housing covers has positioning elements for fixing the housing cover relative to the housing body. The positioning elements fix the housing cover in a form-locking fashion laterally to the housing body. In this way, the housing body is closed securely, since the spring force of the clamp spring only has to act on the housing cover in respect of a possible tensile stress, whereas lateral forces on the housing cover (shear stress) are absorbed by the positioning elements. In addition, the positioning elements simplify the mounting.

In a further advantageous embodiment of the invention, the housing body has a second holding element, which interacts with the base of the at least one clamp spring such that the clamp spring is fixed to the housing. Particularly preferred as a second holding element is a groove in an outer surface of the housing body or a locking apparatus on an outer surface of the housing body, with the locking apparatus completely or partially encompassing the base of the at least one clamp spring. The second holding element offers a further possibility in order to prevent the clamp spring from slipping.

In a further embodiment of the invention, a holding spring is provided in the housing, which fixes a circuit board of the electronic assembly to the housing body. A housing is created in this way, in which it is not only possible to remove the housing cover in a simple fashion but also to assemble and disassemble the electronic assembly.

Further advantageous embodiments of the invention are specified in the dependent claims.

The invention is described in more detail below with reference to an exemplary embodiment with the aid of four figures, in which:

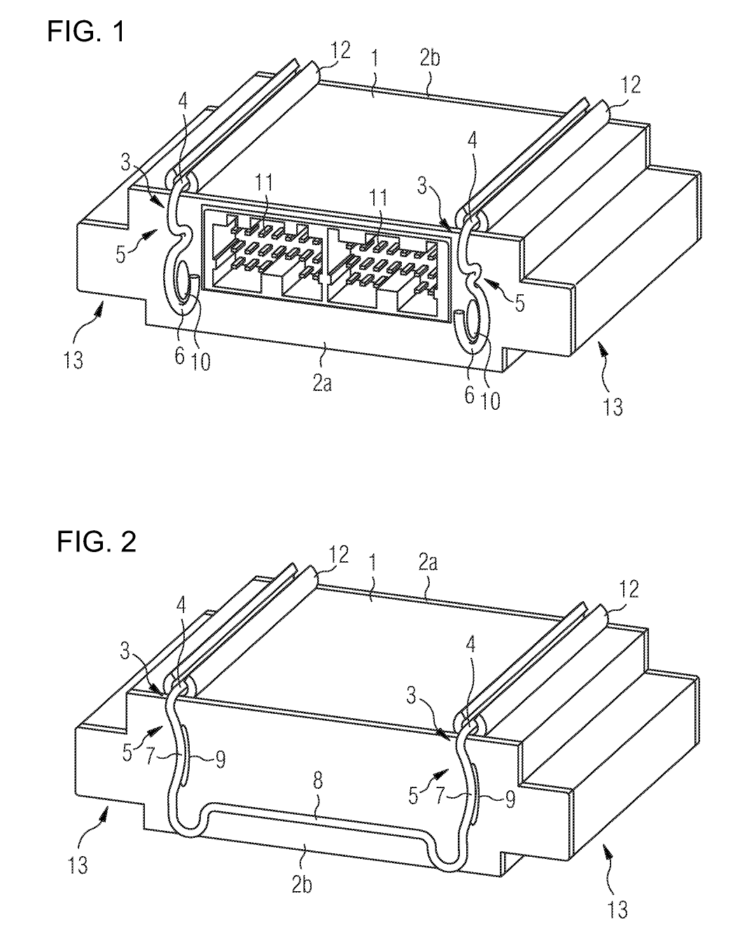

FIG. 1 shows a front view of a perspective representation of a housing for receiving an electronic assembly,

FIG. 2 shows a rear view of a perspective representation of the housing,

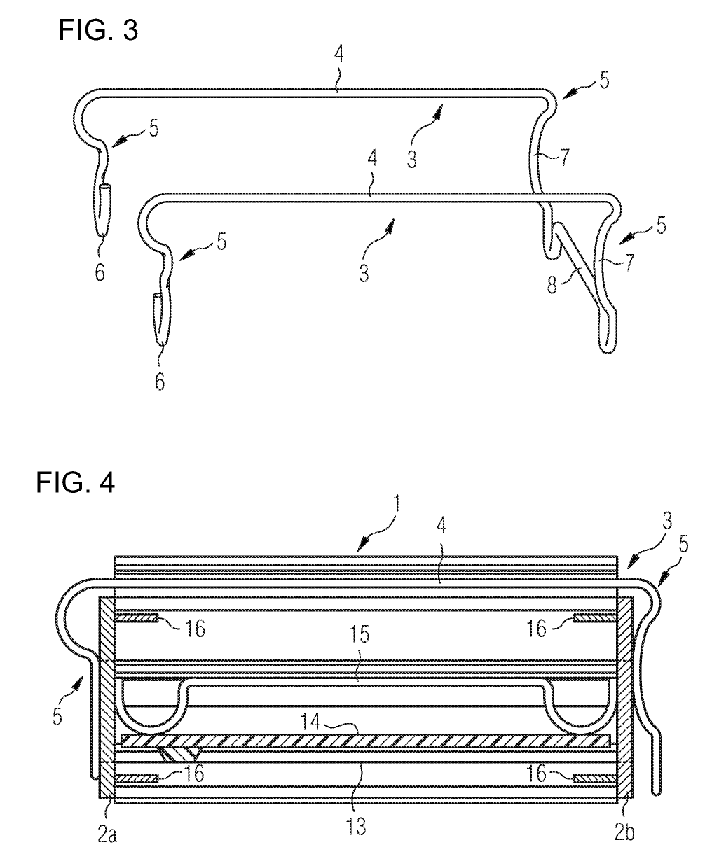

FIG. 3 shows a perspective representation of a clamp spring element with two clamp springs connected by means of a rod

FIG. 4 shows a schematic side view of the housing shown in FIGS. 1 and 2.

The housing shown in a perspective representation in FIG. 1 for receiving an electronic assembly includes a housing body 1 and two housing covers 2a, 2b, which are fixed to the housing body 1 with the aid of two clamp springs 3. The unshaped clamp springs 3 each have a base 4 and two legs 5 running essentially at right angles to the base 4, of which only one is visible in the representation shown in each instance. The ends of the visible legs 5 are bent over to form spring eyes 6. The front housing cover 2a has raised regions 10 on its outer surface, which are completely or partially encompassed by the spring eyes 6 of the clamp springs 3. The front housing cover 2a also has a recess, through which electrical connectors 11 of the electronic assembly arranged inside the housing are accessible. The housing body 1 has two locking apparatuses 12 arranged in parallel on its upper outer surface, in which the base 4 of the clamp springs 3 is placed. The housing body 1 is embodied in a tapered fashion in its cross-section in the outer regions so that a ledge 13 is formed, on which a circuit board of the electrical assembly, which is not visible in this representation, is placed.

The housing body 1 may be a section of an extruded hollow profile or a hollow profile produced using an extrusion method for instance. Aluminum or plastic can be used preferably as material. The running direction (manufacturing direction) of the hollow profile is also referred to below as longitudinal direction of the housing body 1. The use of hollow profiles for housings for receiving electronic assemblies is particularly advantageous, since traversing structural elements can already be embodied in the extruder or extruding press manufacturing methods in the longitudinal direction of the housing body. This relates for instance to the locking apparatuses 12 or receiving elements for the circuit board of the electronic assembly, for instance insertion grooves, bearing rods or also the ledge 13.

The covers 2a, 2b adjusted to the profile of the housing body 1 can be produced in one piece of plastic in an injection molding method for instance. Recesses are provided in the housing cover 2a, through which the electrical connectors 11 of the electronic assembly are accessible, and/or protrude from the housing. The two knob-like raised regions 10 are also molded on the outer surface of the housing cover 2a. Positioning elements fastened to inwardly pointing surfaces of the housing covers 2a, 2b and which fix the housing cover laterally by means of a form-locking connection, in other words in the direction at right angles to the longitudinal direction of the housing body 1, are not visible in the representation. These positioning elements may be pins arranged in the edge or corner region for instance or a ledge running completely or partially parallel to the edge of the housing cover, which preferably engages internally into the housing body 1 or outwardly encompasses the edge of the housing body 1. The positioning elements are favorably connected in one piece with the housing covers 2a, 2b, e.g. by already being molded in the injection molding method for instance.

In accordance with the invention, the housing is closed by the clamp springs 3. The clamp springs 3 have the straight base 4, and the legs 5 which run essentially at right angles thereto, which exert the holding force on the housing covers 2a, 2b. The clamp springs 3 can be bent from spring steel with a round or flattened cross-section and if necessary are then hardened. To amplify the spring effect, the transition between the base 4 and the legs 5 can then be shown here like in FIG. 1 by an arch extending beyond the plane of the housing cover 2a. At its end, the leg 5 is bent over to form a spring eye 6, such that the spring eye 6 rests as planarly as possible on the housing cover 2a and in this way as mentioned above completely or partially encompasses the knob-like, raised region 10 of the housing cover 2a, as a result of which the clamp spring 3 is fixed in its position to the housing. For attachment and removal, the clamp spring 3 can be lifted accordingly by lifting above the raised region 10 and moved into position.

A further measure of holding the clamp springs 3 in their position is provided by the locking apparatuses 12 attached to the housing body 1 and/or molded from the housing body 1. During mounting, the clamp springs 3 are clicked into the locking apparatuses 12 with their base 4, so that the base 4 is partially encompassed by the locking apparatus 12. Alternatively, instead of a locking apparatus emerging from the surface of the housing body 1, a groove embedded in the surface of the housing body 1 is conceivable, into which the base 4 of the clamp spring 3 is positioned.

FIG. 2 shows in a similar representation to FIG. 1 the rear view of the housing in FIG. 1. In contrast to the housing cover 2a on the front side, the rear-sided housing cover 2b in this exemplary embodiment has no recess for the electrical connector 11. Furthermore, instead of the raised regions 10, recesses 9 are introduced in the housing cover 2b.

It is apparent from the representation in FIG. 2 that the two clamp springs 3 are connected to a single clamp spring element by way of a rod 8. Compared with two separate clamp springs, the mounting of the housing is simplified by the clamp spring element. Individual clamp springs could likewise naturally be used in the exemplary embodiment shown, and are preferable for space-saving reasons for instance if the housing cover 2b is also to receive plug-in contacts, connecting elements or operating elements. Instead of the spring eyes 6, the legs 5 of the clamp springs 3 resting on the housing cover 2b have the half moon-shaped regions 7, which engage in the depressions 9 of the housing cover 2b. In terms of efficiency, the combination of the half moon-shaped arched regions 7 and the depressions 9 can be compared with the combination of the spring eyes 6 and the raised regions 10 and optionally used.

In FIG. 3, the clamp spring element used in the exemplary embodiment is shown once again in a perspective representation. The whole element, encompassing the two clamp springs 3 and the rod 8 connecting them can be advantageously bent in one piece from spring wire.

FIG. 4 shows a schematic representation of a cross-sectional view in the longitudinal direction through the housing of the exemplary embodiment. In this view, an already previously mentioned circuit board 14 of the electronic assembly can be seen. The circuit board 14 is placed on both housing sides (left and right in the FIGS. 1 and 2) on the ledge 13. A holding spring 15 is provided in the housing body 1 in order to fix the circuit board 14, said holding spring being inserted herein before closing the housing body 1 and pressing the circuit board 14 onto the ledge 13 with its spring force. In the example shown, this takes place in four pressure points arranged in the edge region of the housing body 1 in each instance. The holding spring 15 is in this case upwardly supported on the inner surface of the housing body 1 in its tapered region. Positioning elements 16 connected to the housing covers 2a, 2b are likewise visible in FIG. 4. As already described above, the positioning elements 16 are used to laterally fix the housing covers 2a, 2b to the housing body 1 in a form-locking fashion.

The housing shown in the exemplary embodiment is particularly suited to receiving an electronic control unit in a mechanically rough, vibrationally-rich environment, e.g. in the automotive field. A circumferential seal can if necessary be provided between the housing body 1 and the housing cover 2a, 2b, by means of which the housing is water or at least spray water tight.

1-14. (canceled)

15. A housing for receiving an electronic assembly, the housing comprising:
a housing body having two mutually opposite openings and two housing covers for closing said openings; and
at least one U-shaped clamp spring having a base and two legs and being configured to be clipped onto the housing with said legs exerting mutually opposite and interacting forces onto said housing covers, for fixing said housing covers to said housing body.

16. The housing according to claim 15, wherein said at least one clamp spring has a locking element on at least one of said legs.

17. The housing according to claim 16, wherein said locking element is formed by a hook-shaped or half moon-shaped arched region of at least one of said legs.

18. The housing according to claim 16, wherein said locking element is formed by a spring eye on an end of at least one of said legs.

19. The housing according to claim 15, wherein said at least one clamp spring is two interconnected clamp springs.

20. The housing according to claim 19, wherein said two clamp springs are interconnected by a rod running at right angles to said bases and at right angles to said legs.

21. The housing according to claim 16, wherein at least one of said housing covers has a retaining element form-lockingly coupled to said locking element of said at least one clamping spring.

22. The housing according to claim 21, wherein said retaining element is a depression in said at least one housing cover.

23. The housing according to claim 21, wherein said retaining element is a raised region of said at least one housing cover.

24. The housing according to claim 15, wherein at least one of said housing covers has positioning elements for fixing said at least one housing cover relative to said housing body.

25. The housing according to claim 15, wherein said housing body has a holding element interacting with said base of said at least one clamp spring for fixing said clamp spring to the housing.

26. The housing according to claim 25, wherein said holding element is a groove in an outer surface of said housing body.

27. The housing according to claim 25, wherein said holding element is a locking apparatus on an outer surface of said housing body configured to completely or partially encompass said base of said at least one clamp spring.

28. The housing according to claim 15, which further comprises a holding spring disposed in the housing for fixing a circuit board of the electronic assembly to said housing body.
